(19) United States
(12) Patent Application Publication
(10) Pub. No.: US 2011/0083607 A1
(43) Pub. Date: Apr. 14, 2011

(54) VAPOR PHASE SELF-ASSEMBLED MONOLAYER COATING APPARATUS

(75) Inventors: Youn Sang You, Gyeonggi-do (KR); Sung Jin Park, Gyeonggi-do (KR); Jun Koo Lee, Gyeonggi-do (KR); Neung Ku Yoon, Gyeonggi-do (KR); Jin Goo Park, Gyeonggi-do (KR)

(73) Assignee: SORONA INC., Pyeongtaek-si (KR)

(21) Appl. No.: 12/996,326

(22) PCT Filed: Jun. 4, 2009
(86) PCT No.: PCT/KR09/03000

§ 371 Date: Dec. 3, 2010

(30) Foreign Application Priority Data
Jun. 5, 2008 (KR) 10-2008-0053096

(51) Int. Cl. C23C 16/455

(52) U.S. Cl. 118/715

(57) ABSTRACT

Provided is a vapor phase self-assembled monolayer (SAM) coating apparatus having a small volume and reduced manufacturing costs. The apparatus includes: a chamber for providing space in which at least one substrate is mounted; one or more injection apparatuses, installed at a side of the chamber and in the form of an injector; and one or more supply units for supplying a liquid precursor into the precursor injection apparatus.

### TECHNICAL FIELD

The present invention relates to a thin film coating apparatus, and more particularly, to a thin film coating apparatus capable of uniformly forming a single-layer polymer thin film.

### BACKGROUND ART

A self-assembled monolayer (SAM) refers to a thin organic monolayer that is spontaneously coated onto a surface of a given substrate and is regularly aligned thereon. In detail, self-assembly refers to a phenomenon in which sub-unit molecules are spontaneously assembled due to interactions between the molecules to form a predetermined structure through a spontaneous reaction. A molecule used in forming a sub-unit of a SAM is formed of three portions. That is, the molecule includes a reaction group as a head portion that is coupled to a substrate, an alkane chain as a body portion that allows regular formation of a monolayer, and a functional group as a tail portion that determines a particular function of the monolayer.

Nano-imprinting lithography (NIL), as an example in which an SAM is applied, is known as a technique that allows mass production of nano patterns at low costs by performing a single lithography process. In an NIL process, a stamp having a nano-structure carved therein is transferred onto a surface of a polymeric resin such as a thermosetting resin or a photocurable resin spin-coated or dispensed onto a substrate. That is, the NIL process causes patterns of the stamp to be transferred to the polymeric resin, which is a material to be transferred, through physical contact.

When two different materials contact each other in the NIL process, an adhesive force exists between interfaces of the two materials, which may cause the materials to adhere to each other. The adhesive force increases as patterns become denser and as line widths of the patterns become smaller, and thus the adhesive force is a critical factor in performing a successful NIL process. In other words, a portion of the polymeric resin may remain on the stamp due to the adhesive force, and transfer of the pattern may be distorted due to the remaining resin and thus the pattern cannot be exactly formed in the material to be transferred. Accordingly, lifetime of the stamp is reduced and production yield is decreased. In order to perform a successful NIL process and to protect the stamp, the resin should be prevented from adhering to the stamp.

One of methods of preventing the resin from adhering to the stamp includes coating the stamp with a self-assembled monolayer having a low surface energy. Examples of methods of forming a SAM are spin coating, a liquid SAM deposition method, a vapor phase SAM deposition method, and a plasma polymerization method. The spin coating and the liquid SAM method uses liquid materials. In particular, when forming a liquid SAM, a substrate formed of a silicon oxide, gold, or platinum may be dipped into a solution in which an organic active material is melted, and then the organic active material may combine with the substrate to spontaneously form a nanometer-scale monolayer.

However, in the spin coating method and the liquid SAM coating method, it is difficult to precisely control an amount of a reactant material during coating, and thus reliability is hard to provide using the spin coating method and the liquid SAM coating method even under the same conditions as other coating methods. In addition, manufacturing processes of minute devices such as semiconductor devices are usually performed in a vapor phase process, and due to characteristics of a liquid such as surface tension, it is difficult to apply a liquid SAM to the manufacturing processes of minute devices.

A precursor used in forming a vapor phase SAM may be a polymeric material that exists as a liquid and thus it may be difficult to uniformly coat minute electronic devices using the precursor. In order to perform coating using a vapor phase SAM method, the liquid needs to be converted into a vapor. However, the liquid is not easily transformed into vapor due to a low vapor pressure of the precursor, and thus an apparatus for vaporization is required additionally.

WO 2005/006398 A1, published on 20 Jan. 2005 and granted to Koblin, Boris, et al., discloses a vapor phase SAM deposition apparatus. The apparatus includes a heating (storage) container used in generating a vapor phase of a precursor when the precursor is located in a container. Depositing of a vapor phase SAM requires at least one precursor and at least one catalyst, and thus storage containers for respectively generating a vapor phase are required. Also, since a 50 to 1000 cc storage container is required to generate a necessary amount of vapor, the storage container increases the size and the price of the apparatus. In addition, a heating apparatus needs to be added to the storage container in order to generate a vapor, and thus the volume of the storage container is increased further, thereby increasing the costs.

In particular, coating used to minute electronic devices, such as nano-imprinting or micro-electrochemical systems (MEMS), requires a plurality of vapor storage containers in order to provide an accurate amount of needed precursor for reaction, and this increases the manufacturing costs. Also, large-volume storage containers occupying a large space increase the size of the thin film deposition apparatus.

### DETAILED DESCRIPTION OF THE INVENTION

### Technical Problem

The present invention provides a vapor phase self-assembled monolayer (SAM) coating apparatus having a small volume and reduced manufacturing costs.

### Technical Solution

According to an aspect of the present invention, there is provided a vapor phase self-assembled monolayer (SAM) coating apparatus, the apparatus comprising: a chamber for providing space in which at least one substrate is mounted; one or more precursor injection apparatuses, installed at a side of the chamber and in the form of an injector; and one or more precursor supply units for supplying a liquid precursor into the precursor injection apparatus.

The precursor injection apparatus may comprise: an injector for accommodating a liquid precursor; an injection needle for supplying a relatively small amount of the precursor accommodated in the injector to the chamber; and a piston for pushing the liquid precursor toward the injection needle. An amount of the liquid precursor accommodated in the injector may be 5 to 50 cc. The precursor injection apparatus may comprise a valve that is installed in the chamber and attached to the injection needle to continuously supply the liquid precursor to the chamber or to stop the supply of the liquid precursor.

The plurality of injectors may supply different precursors, and a single type of precursor may be supplied by each of the plurality of injectors. Also, the precursor injection apparatus may comprise a driving unit for moving the piston toward the injection needle.

The vapor phase SAM coating apparatus may further comprise a vaporization unit that is installed in the chamber and accommodates the liquid precursor supplied from the precursor injection apparatus and converts the precursor into a vapor phase. The vaporization unit may comprise a plurality of flow passages through which the precursor converted into a vapor phase is transferred to the chamber.

The vapor phase SAM coating apparatus may further comprise a heater that is attached on an inner wall or an outer wall of the chamber and controls a temperature of the chamber. Also, the vapor phase SAM coating apparatus o may further comprise a plasma apparatus in the chamber, wherein the plasma apparatus forms a terminal OH group on the substrate.

A pattern for manufacturing minute electronic devices may be formed in the substrate, and a stamp for nano-imprinting lithography (NIL) may be formed on the substrate.

### DESCRIPTION OF THE DRAWINGS

FIG. 1 is a schematic view illustrating a thin film coating apparatus according to an embodiment of the present invention;

FIG. 2 is a cross-sectional view illustrating a precursor injection apparatus according to an embodiment of the present invention;

FIG. 3 is a perspective view illustrating a vaporization unit according to an embodiment of the present invention;

FIG. 4 is a graph showing variation in contact angles according to stabilization temperatures according to an embodiment of the present invention; and

FIG. 5 is a cross-sectional view illustrating a precursor injection apparatus according to another embodiment of the present invention.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

Hereinafter, a vapor phase self-assembled monolayer (SAM) coating apparatus having a small volume and reduced costs and a method of forming a monolayer using the apparatus will be described. A vapor phase SAM may be applied to a substrate on which a pattern for forming an electronic device, particularly, a minute electronic device, is formed. For example, the substrate may be a substrate on which a stamp for nano-imprinting lithography (NIL) is formed or a substrate on which diamonds are arranged. Before describing the apparatus and method, a precursor of a monolayer used in the present invention will be described.

Precursors that are useful for the present invention may be organic precursor materials such as silane, chlorosilane, fluorosilane, methoxy silane, alkylsilane, and aminosilane. Examples of the preferable conventional precursors used in forming a monolayer may be some of trichlorosilane precursors such as fluorodecyltrichlorosilane (FDTS), undecenyltrichlorosilane (UTS), vinyl-trichlorosilane (VTS), decyltrichlorosilane (DTS), octadecyltrichlorosilane (OTS), dimethyldichlorosilane (DDMS), decenyltrichlorosilane (DDTS), fluoro-tetrahydrooctyl trimethylchlorosilane (FOTS), perfluorooctyldimethylchlorosilane, aminopropylmethoxysilane (APTMS), fluoropropylmethyldichlorosilane, and perfluorodecyldimethylchlorosilane. Among these, OTS, DTS, UTS, VTS, DDTS, FOTS, and FDTS are preferable.

A lower end portion of a precursor chain is a saturated hydrocarbon including OTS, DTS, or UTS, and the precursor chain includes a vinyl functional group with respect to VTS or DDTS, and includes a fluorine atom with respect to FDTS having a fluorine atom along most parts of the length of the chain. Other examples of useful precursors may be 3-aminopropyltrimethoxysilane (APTMS) and 3-glycytoxypropylmethoxysilane (GPTMS), which provide an amino functionality. One of ordinary skill in the art of organic chemistry would be aware that predetermined characteristics may be adjusted and provided to a surface of a vapor-deposited coating layer using these precursors.

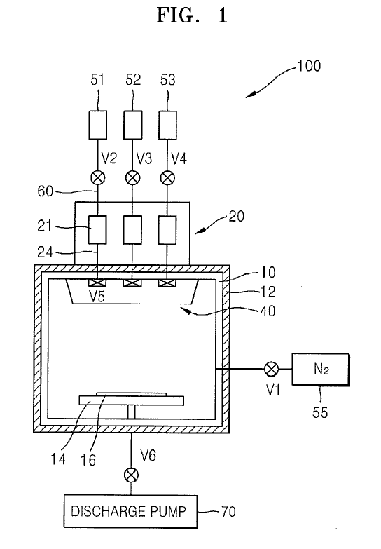

FIG. 1 is a schematic view illustrating a thin film coating apparatus 100 according to an embodiment of the present invention.

Referring to FIG. 1, the coating apparatus 100 includes a unit for supplying a precursor to a precursor injection apparatus 20, the precursor injection apparatus 20, and a unit for depositing a thin film. At least one liquid precursor is supplied to the precursor injection apparatus 20 through a supply line 60 used in supplying the liquid precursor, first through third precursor supply units 51, 52, and 53 are connected to the precursor injection apparatus 20, and second through fourth regulation valves V2, V3, and V4 for controlling the first through third precursor supply units 51, 52, and 53 and supply of the precursor are formed. Here, three precursor supply units are described but the number of supply units may vary according to necessity. According to circumstances, although not shown in FIG. 1, a unit for supplying a purge gas may also be additionally installed.

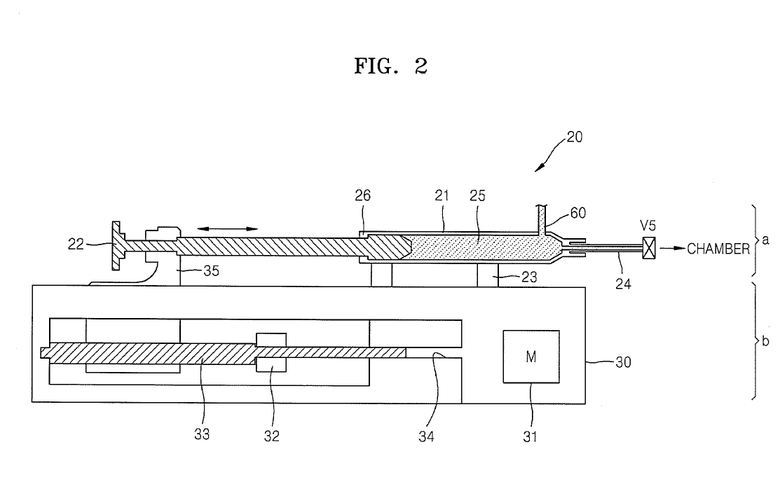

The precursor injection apparatus 20 shows an inventive feature of the present invention and will be described in detail with reference to FIG. 2. Referring to FIG. 2, the precursor injection apparatus 20 is divided into an injection unit (a) that supplies a liquid precursor 25 to a chamber 10 and a driving unit (b) for driving the injection unit (a). The injection unit (a) includes an injector 21 for accommodating the liquid precursor 25, an injection needle 24 for supplying the precursor 25 present in the injector 21 in a relatively small amount to the chamber 10, and a piston 22 for applying a driving force for supplying the precursor 25. The injector 21 is fixed by an injector fixing portion 23, and supply of the precursor 25 to the chamber 10 is stopped or continued through a fifth control valve V5 attached at an end portion of the injection needle 24. The fifth control valve V5 may be installed outside the chamber 10 between a heater 12 and the injector 21.

The driving unit (b) includes a body 30 for supporting the driving unit (b), a motor 31 for providing a driving force, a transferring unit 32 for transferring the driving force generated by the motor 31, and first and second driver 33 and 35 for moving along a straight line according to the driving force transferred by the transferring unit 32. In detail, the driving force generated by the motor 31 is transferred by the transferring unit 32 to cause the first driver 33 to move along a straight line along a guide 34. The motion of the first driver 33 is completely transferred to the second driver 35, which connects the first driver 33 and the piston 22, thereby causing a straight-line motion of the piston 22. The transferring unit 32 and the driving unit (b) may be implemented in any of various manners. According to circumstances, the driving unit (b) may be omitted and the precursor 25 may be injected manually.

The precursor 25 present in the injector 21 is injected into the chamber 10 in the following manner. First, while the fifth control valve V5 is closed, the liquid precursor 25 is supplied to the injector 21 through the supplying line 60. Then the second control valve V2, the third control valve V3, or the fourth control valve V4 is opened, and the piston 22 is moved in a direction away from the chamber 10 until the piston 22 is stopped by a threshold 26 of the injector 21 to fill the injector 21 with a predetermined amount the liquid precursor 25. When the injector 21 is filled with the predetermined amount of the precursor 25, the second control valve V2, the third control valve V3, or the fourth control valve V4 is closed. This process of filling the injector 21 may be performed spontaneously by applying a driving force to the piston 22 or may be performed in a direction opposite to the direction of the piston 22 by applying a predetermined pressure to the first through third precursor supply units 51, 52, and 53.

Next, the supplying line 60 is closed and the fifth control valve V5 is opened, and the second driver 35 is moved toward the chamber 10 to inject the precursor 25 into the chamber 10.

According to necessity, one injector 21 or a plurality of injectors 21 may be installed. For example, one injector 21 may be installed when only one type of precursor is to be injected. When necessary, one type of precursor may be supplied by the one injector 21, the injector 21 may be purged, and then another type of precursor may be supplied to the one injector 21. When one injector 21 is installed, the space of the precursor injection apparatus 20 in the coating apparatus 100 may be minimized, and this case is particularly advantageous when the size of the chamber 10 into which the precursor 25 is supplied is relatively small. A plurality of injectors 21 may be installed when different types of precursors are to be injected into the chamber 10 or one type of precursor is to be injected through the plurality of injectors 21.

The inner capacity of the injector 21 according to the present invention may be preferably 5 to 50 cc. Accordingly, the size of the injector 21 is relatively small compared to the conventional art, and thus the space of the injector 21 in the coating apparatus 100 may be reduced greatly. Also, as a relatively small amount of a precursor is supplied to the chamber 10, the liquid precursor 25 may be easily converted into a vapor phase. When forming a typical vapor phase SAM, about 5 to 50 cc of a precursor may be required, and for vaporization, 0.01 to 1 cc of the precursor may be injected several times via the injector 21 to thereby provide the precursor. For example, when the injector 21 is filled with the precursor, the amount of the precursor filled in the injector 21 is sufficient to perform the injection process at least 50 times and at most 5000 times.

The unit for depositing a thin film includes a substrate mounting portion 14 where a substrate 16 on which a monolayer is to be formed is formed in the chamber 10 to provide a space for depositing a thin film. A vaporization unit 40 for vaporizing a precursor for forming a monolayer is installed over the substrate 16. The heater 12 is attached on an outer wall of the chamber 10 in order to control an inner temperature of the chamber 10, and a purge gas supply unit 55 for supplying a purge gas such as N₂ and a first control valve V1 for controlling supply of the purge gas are installed outside the chamber 10. Alternatively, the heater 12 may be installed on an inner wall of the chamber 10.

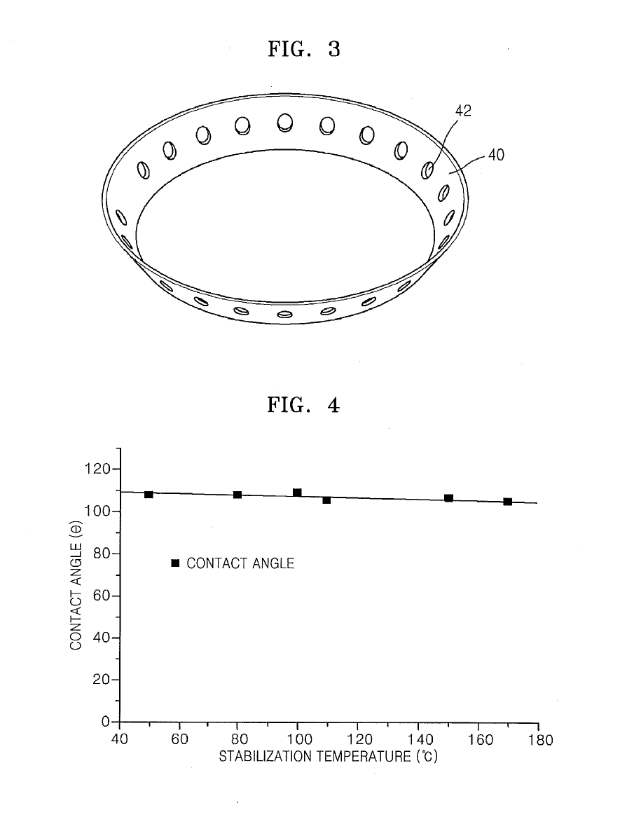

Referring to FIG. 3, the vaporization unit 40 temporarily accommodates a precursor that is injected into the vaporization unit 40 by the precursor injection apparatus 20, and vaporizes the precursor using heat generated by the heater 12. In detail, the precursor is vaporized in the vaporization unit 40 and passes into the chamber 10 through a flow passage 42. The vaporization unit 40 prevents the precursor from directly contacting the substrate 16 and maintains a uniform vapor pressure in the chamber 10 so that a monolayer may be uniformly coated on the substrate 16.

The shape and size of the vaporization unit 40 may be varied according to the coating apparatus 100. For example, when the chamber 10 is relatively large, the size of the vaporization unit 40 may increase; when the chamber 10 is relatively small, the size of the vaporization unit 40 may decrease. Also, the shape and number of passages of the flow passage 42 may be varied according to vaporization characteristics of the precursor.

The substrate 16 may have any of various shapes according to usage (e.g., a stamp used in nano-imprinting). In order to couple a chloro-functional group onto a surface of the substrate 16, a terminal OH group may be preferably generated on the surface of the substrate 16. This process is referred to as a preliminary process performed on the substrate 16. The terminal OH group may be generated by processing a Piranah solution (Sulfuric acid Peroxide Mixture, SPM) outside the chamber 10, or by purging H₂O vapour from the chamber 10 or by processing O₂ plasma or H₂O plasma inside the chamber 10.

In general, the terminal OH group is usually generated by processing O₂ plasma under an atmosphere containing water. The O₂ plasma is generated by applying radio-frequency (RF) power to a shower head (not shown) through which oxygen is supplied. Accordingly, the preliminary process of the substrate 16 may be performed in the chamber 10 when the substrate 16 is mounted therein or the terminal OH group may be generated in a separate chamber and transported to the chamber 10. In the preliminary process of the substrate 16, while the substrate 16 is exposed to oxygen plasma, a pressure in the chamber 10 may generally be preferably maintained at 0.5 to 5 Torr, and a flow amount of oxygen may be preferably maintained at 50 to 150 sccm. Also, the substrate 16 may be exposed to oxygen plasma for preferably 1 to 5 minutes. The heater 12 is used to maintain a uniform temperature in the chamber 10 to control a vapor pressure of the precursor that is vaporized in the vaporization unit 40.

Hereinafter, the present invention will be described in detail by describing deposition of a vapor phase SAM using mainly FOTS, which is a type of chloro-silane precursor. When forming a monolayer using FOTS, the FOTS, as a coating precursor and here referred to as a first precursor, and a vapor precursor, as is a catalyst and here referred to as a second precursor, are required. The first precursor is supplied from the first supply unit 51 and a second precursor is supplied from the second supply unit 52. Here, the third supply unit 53 is not used.

In order to deposit the vapor phase SAM, vaporization of a precursor is necessary. To this end, frequently, the precursor in a liquid state is evaporated by being heated. This method is effective with a precursor that vaporizes relatively easily but ineffective in that vaporization with respect to a polymeric precursor is relatively slow. In order to solve this problem, the precursor injection apparatus 20 is used according to the current embodiment of the present invention. The precursor injection apparatus 20 greatly reduces the amount of a liquid precursor accommodated in the injector 21 to facilitate vaporization. Also, the amount of the precursor to be injected into the chamber 10 is injected in a relatively small amount using the injection needle 24, thereby maximizing the vaporization speed.

In order to deposit a monolayer, first, a sixth control valve V6 is opened and air in the chamber 10 removed using a discharge pump 70, and then the fifth control valve V5 is opened and the injector 21 is vacuumized. Then the fifth and sixth control valves V5 and V6 are closed, and the second control valve V2 connected to the first supply unit 51 is opened to supply the first precursor, FOTS, into the injector 21 and then the second control valve V2 is closed. Here, the amount of the precursor injected into the injector 21 is about 5 to 50 cc.

Next, the inner portion of the chamber 10 is heated using the heater 12 to adjust a temperature of the substrate 16 to a predetermined temperature. Then, as described above, the fifth control valve V5 is opened to discharge 0.1 to 1 cc of the first precursor, for example, the liquid precursor 25, to the vaporization unit 40 through the injection needle 24, and then the fifth control valve V5 is closed to vaporize the precursor 25 to form a uniform vapor pressure in the chamber 10, and this state is maintained for a predetermined period of time so that the precursor 25 vaporized at a predetermined pressure may uniformly form a monolayer on the substrate 16.

In order to supply the second precursor, the first control valve V1 and the sixth control valve V6 are opened to purge the chamber 10. Then, the first control valve V1 and the sixth control valve V6 are closed and the third control valve V3 is opened to supply the second precursor into the injector 21. Next, using the same method used for the first precursor, the second precursor is injected into the chamber 10 and then the sixth control valve V6 is closed and the closed state of the chamber 10 is maintained for a predetermined period of time, preferably for about 3 to 10 minutes, so as to induce reactions between the first and second precursors to form a monolayer on the substrate 16.

In the current embodiment of the present invention, two types of precursors are used to deposit a vapor phase SAM but three or more types of precursors may also be used to deposit a vapor phase SAM. The number of injectors 21 and the size of the vaporization unit 40 may be modified according to optimum coating conditions.

A coating operation is performed at a pressure of about 0.1 to 10 Torr. When FOTS or DDMS is used, which are coating precursors used in combination with a water catalyst, the temperature of the substrate 16 may generally be about 20 to 200□. In order to maintain the vapor phase of the coating precursors before starting reactions, the temperature of the substrate 16 may be maintained at about 20 to 200□. According to the chemical composition and the material of the substrate 16, at a predetermined temperature, it takes about three minutes to several hours to coat the entire surface of a silicon substrate with a continuous monolayer using the coating precursors. If FOTS or DDMS is used as a coating precursor, about 5 to 30 minutes are generally required for coating.

Also, after the vapor phase SAM is deposited, the vapor phase SAM may preferably be stabilized by being maintained at a predetermined temperature for a predetermined period of time. The temperature and time period of stabilization vary according to the combination of precursors. For DDMS, the stabilization process may preferably be performed at 20 to 200□ and for about 3 to 20 minutes. For FOTS, the stabilization process may preferably be performed at 20 to 200□ and for about 3 to 20 minutes.

FIG. 4 is a graph showing variation in contact angles according to stabilization temperatures according to an embodiment of the present invention. Contact angles refer to a condensed state of a fluid such as water droplets dropped on a substrate, condensed due to surface tension. The greater the contact angles, the smaller the surface tension. A contact angle may preferably be greater than 90°.

As illustrated in FIG. 4, when FOTS is used as a precursor, a monolayer that has undergone a stabilization process has a contact angle greater than 100° at stabilization temperatures within about 50 to 180□. When the contact angle is greater than 100°, it is less likely that foreign substances are adsorbed by the monolayer due to surface tension. Accordingly, the monolayer according to the current embodiment of the present invention prevents adherence to a polymeric resin of a material to be transferred, and thus may be applied to manufacturing of minute electronic devices.

According to the coating apparatus 100 of the current embodiment of the present invention, a relatively small amount of a liquid precursor, such as 0.01 to 1 cc, is vaporized. Accordingly, the volume of the coating apparatus 100 and costs thereof may be significantly reduced compared to the conventional art where a storage container of 50 to 10000 cc is required. Also, a heating apparatus for generating vapor in the storage container is omitted, and instead a vaporization unit and a heater for controlling a temperature in a chamber are used, thereby significantly reducing the volume of the vaporization unit for vaporizing a precursor in the coating apparatus and the costs thereof.

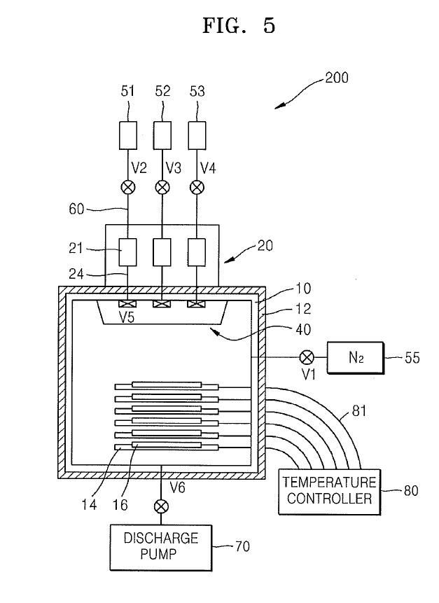

FIG. 5 is a cross-sectional view illustrating a thin film coating apparatus 200 according to another embodiment of the present invention. The coating apparatus 200 is the same as the coating apparatus 100 described with reference to FIGS. 1 through 3 except that a plurality of substrates 16 mounted inside the chamber 10 are included. Accordingly, like reference numerals denote like elements having the same structure and the same function, and thus descriptions thereof will be omitted. Also, the characteristics of the contact angles of monolayers formed on the substrates 16 are the same as those of the coating apparatus 100 described with reference to FIG. 4.

Referring to FIG. 5, the plurality of substrates 16 are respectively mounted to a plurality of substrate mounting units 14. The substrates 16 may preferably have the same temperatures. However, the substrates 16 may not be heated by the heater 12 uniformly. Accordingly, after respectively connecting a temperature controller 80 and the substrates 16 via electric lines 81, the temperatures of the substrates 16 are adjusted to be equal using the temperature controller 80. Thus, monolayers may be formed on the plurality of substrates 16 at the same time.

### INDUSTRIAL APPLICABILITY

According to the coating apparatus of the present invention, 5 to 50 cc of a liquid precursor is vaporized in units of a relatively small amount of 0.01 to 1 cc, and thus the volume of the vaporization unit in the coating apparatus and the costs thereof may be significantly reduced. Also, a heating apparatus that is added to a storage container to generate vapor in the storage container is removed but a heater for controlling a temperature in the chamber and a vaporization unit are used, thereby significantly reducing the volume of the vaporization unit in the coating apparatus and costs thereof.

While the present invention has been particularly shown and described with reference to exemplary embodiments thereof, the invention is not limited thereto, and it will be understood by those of ordinary skill in the art that various changes in form and details may be made therein without departing from the spirit and scope of the invention.

1. A vapor phase self-assembled monolayer (SAM) coating apparatus, the apparatus comprising:
a chamber for providing space in which at least one substrate is mounted;
one or more precursor injection apparatuses, installed at a side of the chamber and in the form of an injector; and
one or more precursor supply units for supplying a liquid precursor into the precursor injection apparatus.

2. The vapor phase SAM coating apparatus of claim 1, wherein the precursor injection apparatus comprises:
an injector for accommodating a liquid precursor;
is an injection needle for supplying a relatively small amount of the precursor accommodated in the injector to the chamber; and
a piston for pushing the liquid precursor toward the injection needle.

3. The vapor phase SAM coating apparatus of claim 1, wherein an amount of the liquid precursor accommodated in the injector is 5 to 50 cc.

4. The vapor phase SAM coating apparatus of claim 2, wherein the precursor injection apparatus comprises a valve that is installed in the chamber and attached to the injection needle to continuously supply the liquid precursor to the chamber or to stop the supply of the liquid precursor.

5. The vapor phase SAM coating apparatus of claim 1, wherein the plurality of injectors supply different precursors.

6. The vapor phase SAM coating apparatus of claim 1, wherein a single type of precursor is supplied by each of the plurality of injectors.

7. The vapor phase SAM coating apparatus of claim 2, wherein the precursor injection apparatus comprises a driving unit for moving the piston toward the injection needle.

8. The vapor phase SAM coating apparatus of claim 1, further comprising a vaporization unit that is installed in the chamber and accommodates the liquid precursor supplied from the precursor injection apparatus and converts the precursor into a vapor phase.

9. The vapor phase SAM coating apparatus of claim 8, wherein the vaporization unit comprises a plurality of flow passages through which the precursor converted into a vapor phase is transferred to the chamber.

10. The vapor phase SAM coating apparatus of claim 1, further comprising a heater that is attached on an inner wall or an outer wall of the chamber and controls a temperature of the chamber.

11. The vapor phase SAM coating apparatus of claim 1, further comprising a plasma apparatus in the chamber, wherein the plasma apparatus forms a terminal OH group on the substrate.

12. The vapor phase SAM coating apparatus of claim 1, wherein a pattern for manufacturing minute electronic devices is formed in the substrate.

13. The vapor phase SAM coating apparatus of claim 1, wherein a stamp for nano-imprinting lithography (NIL) is formed on the substrate.

14. The vapor phase SAM coating apparatus of claim 1, wherein diamonds are arranged on the substrate.

15. The vapor phase SAM coating apparatus of claim 1, further comprising a temperature controller controlling temperatures of the plurality of substrates.
